(19) United States
(12) Patent Application Publication
(10) Pub. No.: US 2012/0153485 A1
(43) Pub. Date: Jun. 21, 2012

(54) SEMICONDUCTOR DEVICE AND METHOD OF FORMING THE SAME

(75) Inventor: Takashi KANSAKU, Tokyo (JP)

(73) Assignee: ELPIDA MEMORY, INC., Tokyo (JP)

(21) Appl. No.: 13/311,009

(22) Filed: Dec. 5, 2011

(30) Foreign Application Priority Data
Dec. 17, 2010 (JP) 2010-281873

(51) Int. Cl. H01L 23/498

(52) U.S. Cl. 257/762; 257/763; 257/E23.06

(57) ABSTRACT

A device may includes a first conductive film, a first insulating film, a second conductive film, a third conductive film, and a fourth conductive film. The first conductive film includes copper. The first insulating film is disposed over the first conductive film. The first insulating film has a first contact hole. The contact hole reaches a first surface of the first conductive film. The second conductive film includes aluminum. The second conductive film is disposed in the first contact hole. The third conductive film includes titanium nitride. The third conductive film is disposed in the contact hole. The third conductive film covers a part of the first surface of the first conductive film. The fourth conductive film is free of titanium nitride. The fourth conductive film is disposed between the second and third conductive films.

### BACKGROUND OF THE INVENTION

1. Field of the Invention

The present invention generally relates to a semiconductor device and to a method for forming a semiconductor device.

Priority is claimed on Japanese Patent Application No. 2010-281873, filed Dec. 17, 2010, the content of which is incorporated herein by reference.

2. Description of the Related Art

An aluminum reflow process has been known as a method of forming a wiring and a contact plug of a semiconductor device in the same process, using aluminum (Al).

Japanese Unexamined Patent Application, First Publication, No. JP-A-H9-69564 discloses the aluminum reflow process in which an aluminum film formed by sputtering is fluidized by heating at 400° C. or more to fill a contact hole.

In recent years, copper (Cu) which has low electrical resistivity has been used as a material for wirings of the semiconductor device. Since a natural oxidation film is easily formed on a surface of copper, copper is not suitable for the top layer of the wiring when wire bonding or the like is performed. Therefore, when performing the wire bonding, the top layer of the wiring is generally made of an aluminum film.

For example, an aluminum wiring pattern which is made of an aluminum film and includes wirings and contact plugs is formed on a copper wiring by the aluminum reflow process. In this case, a reaction between aluminum in the aluminum film and copper in the copper wiring occurs at the bottom of the contact plug by heat applied in the aluminum reflow process. Therefore, a barrier film is necessarily provided in order to avoid the reaction.

If the reaction between aluminum and copper is occurred at the bottom of the contact plug, an alloy having a high electrical resistivity is formed, which causes a malfunction of the semiconductor device. As the barrier layer described above, a titanium nitride (TiN) film is mainly used.

### SUMMARY

In one embodiment, a device may include, but is not limited to, a first conductive film, a first insulating film, a second conductive film, a third conductive film, and a fourth conductive film. The first conductive film includes copper. The first insulating film is disposed over the first conductive film. The first insulating film has a first contact hole. The contact hole reaches a first surface of the first conductive film. The second conductive film includes aluminum. The second conductive film is disposed in the first contact hole. The third conductive film includes titanium nitride. The third conductive film is disposed in the contact hole. The third conductive film covers a part of the first surface of the first conductive film. The fourth conductive film is free of titanium nitride. The fourth conductive film is disposed between the second and third conductive films.

In another embodiment, a device may include, but is not limited to, a first conductive film, a second conductive film, a third conductive film. The first conductive film includes copper. The second conductive film includes a titanium nitride containing layer and a titanium nitride free layer. The titanium nitride containing layer is in contact with the first conductive film. The third conductive film includes aluminum. The third conductive film is in contact with the titanium nitride free layer.

In still another embodiment, a semiconductor device may include, but is not limited to, a semiconductor substrate, a first interlayer insulating film, a first conductive film, a second interlayer insulating film, a contact plug, and an interconnect. The first interlayer insulating film is disposed over the semiconductor substrate. The first interlayer insulating film has a groove. The first conductive film includes copper. The first conductive film is disposed in the groove. The second interlayer insulating film is disposed over the first conductive film. The second interlayer insulating film has a contact hole reaching the first conductive film. The contact plug is disposed in the contact hole. The contact plug is in contact with the first conductive film. The contact plug includes second, third, and fourth conductive films. The second conductive film is in contact with the first conductive film. The second conductive film includes titanium nitride. The third conductive film is free of titanium nitride. The third conductive film is positioned between the second conductive film and the fourth conductive film. The third conductive film is positioned between the fourth conductive film and the second interlayer insulating film. The fourth conductive film includes aluminum. The interconnect extends over the contact plug and the second interlayer insulating film. The interconnect is coupled to the first conductive film through the contact plug.

### BRIEF DESCRIPTION OF THE DRAWINGS

The above features and advantages of the present invention will be more apparent from the following description of certain preferred embodiments taken in conjunction with the accompanying drawings, in which:

FIG. 1 is a fragmentary cross sectional elevation view illustrating a semiconductor device in accordance with a first preferred embodiment of the present invention;

FIG. 2 is a fragmentary cross sectional elevation view illustrating the semiconductor device in a step involved in a method of forming the semiconductor device of FIG. 1 in accordance with a first preferred embodiment of the present invention;

FIG. 3 is a fragmentary cross sectional elevation view illustrating the semiconductor device in a step, subsequent to FIG. 2, involved in the method of forming the semiconductor device of FIG. 1 in accordance with a first preferred embodiment of the present invention;

FIG. 4 is a fragmentary cross sectional elevation view illustrating the semiconductor device in a step, subsequent to FIG. 3, involved in the method of forming the semiconductor device of FIG. 1 in accordance with a first preferred embodiment of the present invention;

FIG. 5 is a fragmentary cross sectional elevation view illustrating the semiconductor device in a step, subsequent to FIG. 4, involved in the method of forming the semiconductor device of FIG. 1 in accordance with a first preferred embodiment of the present invention;

FIG. 6 is a fragmentary cross sectional elevation view illustrating the semiconductor device in a step, subsequent to FIG. 5, involved in the method of forming the semiconductor device of FIG. 1 in accordance with a first preferred embodiment of the present invention;

FIG. 7 is a fragmentary cross sectional elevation view illustrating the semiconductor device in a step, subsequent to FIG. 6, involved in the method of forming the semiconductor device of FIG. 1 in accordance with a first preferred embodiment of the present invention;

FIG. 8 is a fragmentary cross sectional elevation view illustrating the semiconductor device in a step, subsequent to FIG. 7, involved in the method of forming the semiconductor device of FIG. 1 in accordance with a first preferred embodiment of the present invention;

FIG. 9 is a fragmentary cross sectional elevation view illustrating the semiconductor device in a step, subsequent to FIG. 8, involved in the method of forming the semiconductor device of FIG. 1 in accordance with a first preferred embodiment of the present invention;

FIG. 10 is a fragmentary cross sectional elevation view illustrating the semiconductor device in a step, subsequent to FIG. 9, involved in the method of forming the semiconductor device of FIG. 1 in accordance with a first preferred embodiment of the present invention; and

FIG. 11 is a fragmentary cross sectional elevation view illustrating the semiconductor device in a step, subsequent to FIG. 10, involved in the method of forming the semiconductor device of FIG. 1 in accordance with a first preferred embodiment of the present invention.

### DETAILED DESCRIPTION OF THE PREFERRED EMBODIMENTS

When the titanium nitride film which is the barrier film is thickened in order to secure the barrier property, a semiconductor substrate on which the contact plug is formed is bent because the titanium nitride film is a high compressive stress film.

If the semiconductor substrate is bent, the semiconductor substrate cannot be held stably in apparatuses for forming the semiconductor device in the following manufacturing steps.

If the bent semiconductor substrate is forced to be held on a stage or the like in the apparatuses for forming the semiconductor device, the semiconductor substrate may be broken.

Embodiments of the invention will be now described herein with reference to illustrative embodiments. Those skilled in the art will recognize that many alternative embodiments can be accomplished using the teaching of the embodiments of the present invention and that the invention is not limited to the embodiments illustrated for explanatory purpose.

In one embodiment, a device may include, but is not limited to, a first conductive film, a first insulating film, a second conductive film, a third conductive film, and a fourth conductive film. The first conductive film includes copper. The first insulating film is disposed over the first conductive film. The first insulating film has a first contact hole. The contact hole reaches a first surface of the first conductive film. The second conductive film includes aluminum. The second conductive film is disposed in the first contact hole. The third conductive film includes titanium nitride. The third conductive film is disposed in the contact hole. The third conductive film covers a part of the first surface of the first conductive film. The fourth conductive film is free of titanium nitride. The fourth conductive film is disposed between the second and third conductive films.

In some cases, the device may include, but is not limited to, the third conductive film being in contact with the part of the first surface of the first conductive film.

In some cases, the device may include, but is not limited to, the fourth conductive film disposed between the first insulating film and the second conductive film outside the first contact hole.

In some cases, the device may include, but is not limited to, the fourth conductive film which is a titanium film.

In some cases, the device may include, but is not limited to, the fourth conductive film which is a metal film free of titanium nitride.

In some cases, the device may include, but is not limited to, the fourth conductive film further covering a side surface of the first contact hole.

In some cases, the device may include, but is not limited to, the second conductive film including an alloy containing aluminum.

In some cases, the device may include, but is not limited to, the fourth conductive film being in contact with the second conductive film.

In some cases, the device may include, but is not limited to, the second conductive film including a contact plug and an interconnect. The contact plug is disposed in the first contact hole. The interconnect extends over the first insulating film. The third and fourth films are disposed between the contact plug and the first conductive film.

In some cases, the device may further include, but is not limited to, a second insulating film having a groove in which the first conductive film is disposed. The second insulating film extends under the first insulating film.

In another embodiment, a device may include, but is not limited to, a first conductive film, a second conductive film, a third conductive film. The first conductive film includes copper. The second conductive film includes a titanium nitride containing layer and a titanium nitride free layer. The titanium nitride containing layer is in contact with the first conductive film. The third conductive film includes aluminum. The third conductive film is in contact with the titanium nitride free layer.

In some cases, the device may further include, but is not limited to, a first interlayer insulating film between the first conductive film and the third conductive film. The first interlayer insulating film has a contact hole reaching the first conductive film. The titanium nitride containing layer is disposed in the first contact hole.

In some cases, the device may include, but is not limited to, the titanium nitride containing layer covering a side surface of the contact hole.

In some cases, the device may include, but is not limited to, the titanium nitride free layer made of titanium.

In some cases, the device may include, but is not limited to, the third conductive film including a contact plug and an interconnect. The contact plug is disposed in the first contact hole. The interconnect extends over the first insulating film. The second conductive film is disposed between the contact plug and the first conductive film.

In still another embodiment, a semiconductor device may include, but is not limited to, a semiconductor substrate, a first interlayer insulating film, a first conductive film, a second interlayer insulating film, a contact plug, and an interconnect. The first interlayer insulating film is disposed over the semiconductor substrate. The first interlayer insulating film has a groove. The first conductive film includes copper. The first conductive film is disposed in the groove. The second interlayer insulating film is disposed over the first conductive film. The second interlayer insulating film has a contact hole reaching the first conductive film. The contact plug is disposed in the contact hole. The contact plug is in contact with the first conductive film. The contact plug includes second, third, and fourth conductive films. The second conductive film is in contact with the first conductive film. The second conductive film includes titanium nitride. The third conductive film is free of titanium nitride. The third conductive film is positioned between the second conductive film and the fourth conductive film. The third conductive film is positioned between the fourth conductive film and the second interlayer insulating film. The fourth conductive film includes aluminum. The interconnect extends over the contact plug and the second interlayer insulating film. The interconnect is coupled to the first conductive film through the contact plug.

In some cases, the semiconductor device may include, but is not limited to, the interconnect including the third and fourth conductive films. The third conductive film is in contact with a surface of the second interlayer insulating film.

In some cases, the semiconductor device may include, but is not limited to, the second conductive film covering a side surface of the contact hole.

In some cases, the semiconductor device may include, but is not limited to, the third conductive film made of titanium.

In some cases, the semiconductor device may include, but is not limited to, the second conductive film being in contact with the third conductive film. The third conductive film is in contact with the fourth conductive film.

Hereinafter, a semiconductor device according to an embodiment of the invention will be described in detail with reference to the drawings. As a convenience, in assisting understanding the features thereof, the drawings used in the following descriptions sometimes show such features enlarged, and the dimensional ratios and the like of constituent elements are not necessarily the same as a real semiconductor device. Also, the raw materials and dimensions and the like given as examples in the following descriptions are only examples, and the present invention is not restricted thereto, it being possible to embody arbitrarily variations within a scope that does not change the essence thereof.

### FIRST EMBODIMENT

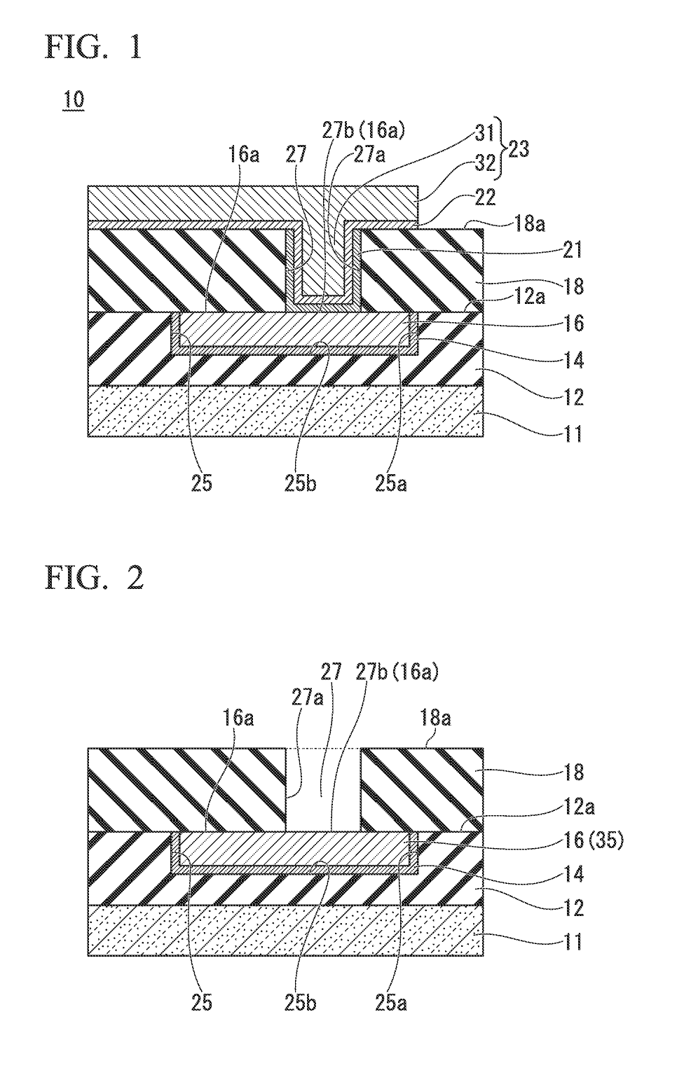

FIG. 1 is a fragmentary cross sectional elevation view illustrating a semiconductor device in accordance with a first preferred embodiment of the present invention.

As shown in FIG. 1, a semiconductor device 10 according to the present embodiment may include, but is not limited to, a semiconductor substrate 11, a first interlayer insulating film 12, a barrier film for a copper wiring 14, a copper (Cu) wiring 16, a second interlayer insulating film 18, a first conductive film 21, a second conductive film 22, and an aluminum wiring pattern 23.

The semiconductor substrate 11 is a plate substrate. For example, a silicon substrate may be used as the semiconductor substrate 11.

The first interlayer insulating film 12 is provided over the semiconductor substrate 11. The first interlayer insulating film 12 has a groove 25 defined by inner surfaces corresponding to a side surface 25a and a bottom surface 25b. The copper wiring 16 is formed in the groove 25. As the first interlayer insulating film 12, a silicon oxide film (SiO₂ film) may be used, for example.

The barrier film for the copper wiring 14 covers the side surface 25a and the bottom surface 25b of the groove 25. The barrier film for the copper wiring 14 is provided for preventing diffusion of copper in the copper wiring 16 into the first interlayer insulating film 12. The barrier film for the copper wiring 14 may be, for example, a lamination of a tantalum nitride film (TaN film) and a tantalum film (Ta film).

The copper wiring 16 is provided on the bather film for the copper wiring 14 and fills the groove 25. A top surface 16a of the copper wiring 16 is substantially flat. The top surface 16a is substantially flush with the top surface 12a of the first interlayer insulating film 12.

The second interlayer insulating film 18 is provided over the top surface 12a of the first interlayer insulating film 12 and the top surface 16a of the copper wiring 16. The second interlayer insulating film 18 has a contact hole 27 defined by inner surfaces corresponding to a side surface 27a and a bottom surface 27b. A portion of the top surface 16a of the copper wiring 16 is shown from the contact hole 27. The bottom surface 27b of the contact hole 27 corresponds to the top surface 16a of the copper wiring 16.

The first conductive film 21 covers the side surface 27a and the bottom surface 27b of the contact hole 27. A portion of the aluminum wiring pattern 23 is formed in the contact hole 27. The bottom surface 27b corresponds to the top surface 16a of the copper wiring 16. The first conductive film 21 is a barrier film including a titanium nitride film (TiN film) having high compressive stress. The titanium nitride film is provided to prevent copper (Cu) in the copper wiring 16 from reacting aluminum (Al) in the aluminum wiring pattern 23 when an aluminum film (not shown) which is a base material of the aluminum wiring pattern 23 is annealed.

In this manner, when the aluminum film (not shown) which is the base material of the aluminum wiring pattern 23 is annealed, the first conductive film 21 which is the barrier film including titanium nitride film prevents the formation of the alloy having the high electrical resistivity, which is caused by reacting copper in the copper wiring 16 and aluminum in the aluminum wiring pattern 23. The first conductive film 21 is formed on only the side surface 27a and the bottom surface 27b of the contact hole 27. The bottom surface 27b corresponds to the top surface 16a of the copper wiring 16, which is shown through the contact hole 27. Therefore, an area where the titanium nitride film is formed is smaller than in the case where the first conductive film 21 is formed on the top surface 18a of the second interlayer insulating film 18, where the aluminum wiring pattern 23 is formed. Hence, a stress caused by the titanium nitride film and applied to the semiconductor substrate 11 can be eased.

The warp of the semiconductor substrate 11 caused by the titanium nitride film can be reduced while the formation of the alloy having the high electrical resistivity, which is caused by the reaction between aluminum in the aluminum wiring pattern 23 and copper in the copper wiring 16, can be prevented.

The first conductive film 21 may be, but is not limited to, a single layer of the titanium nitride film or a lamination of the titanium nitride film and other metal film (for example, a titanium film (Ti film), a tantalum film (Ta film), a tungsten film (W film), or a film of nitride of titanium, tantalum, or tungsten).

When the single layer of the titanium nitride film is used as the first conductive film 21, the thickness of the first conductive film 21 may be, but is not limited to, 30 nm

The second conductive film 22 covers the top surface 18a of the second interlayer insulating film 18, which corresponds to the area where the aluminum wiring pattern 23 is formed. Also, the second conductive film 22 covers the first conductive film 21 in the contact hole 27. In other words, the second conductive film 22 is positioned between the aluminum wiring pattern 23 and the first conductive film 21 and between the aluminum wiring pattern 23 and the second interlayer insulating film 18. The second conductive film 22 is a conductive film which does not include the titanium nitride film which has high compressive stress.

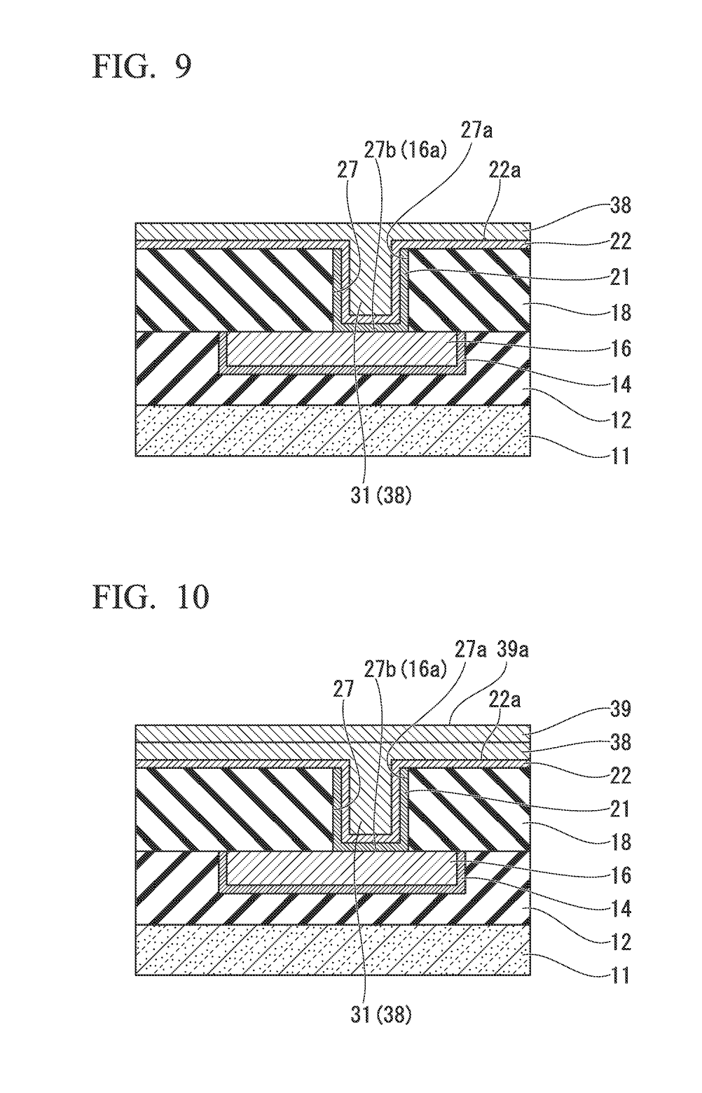

The second conductive film 22 can be formed a metal film facilitating a fluidization (reflowing) of the aluminum film (refer to FIG. 9 described later) when the aluminum film is annealed. The aluminum film is the base material of the aluminum wiring pattern 23.

For example, a single layer of the titanium film (Ti film) may be used as the second conductive film 22. When the single layer of the titanium film (Ti film) is used as the second conductive film 22, the thickness of the second conductive film 22 may be, but is not limited to, 20 nm.

The second conductive film 22 is not limited to the single layer of the titanium film but may be a film which does not include the titanium nitride film having high compressive stress. For example, a lamination of metal films which are not the titanium nitride film may be used as the second conductive film 22.

Considering the annealing process illustrated in FIG. 9, in the case where the second conductive film 22 is the lamination, the titanium film is preferable as the top film of the lamination since the titanium film facilitates a fluidization (reflowing) of the first aluminum film 38.

The aluminum wiring pattern 23 includes a contact plug 31 and a wiring 32. The contact plug 31 is formed on the first and second conductive films 21 and 22 and fills the contact hole 27. The contact plug 31 is electrically coupled to the copper wiring 16 via the first and second conductive films 21 and 22.

The wiring 32 is provided on the second conductive film 22 which is formed on the top surface 18a of the second interlayer insulating film 18. The wiring 32 is united to the contact plug 31. The wiring 32 is electrically coupled to the copper wiring 16 via the contact plug 31.

A material of the aluminum wiring pattern 23 described above may be, but is not limited to, an alloy including aluminum, for example, Al-Si-Cu alloy.

According to the semiconductor device 10 of the present embodiment, when the aluminum film (not shown) which is the base material of the aluminum wiring pattern 23 is annealed, the first conductive film 21 which is the barrier film including titanium nitride film prevents the formation of the alloy having the high electrical resistivity, which is caused by reacting copper in the copper wiring 16 and aluminum in the aluminum wiring pattern 23. The first conductive film 21 is formed on only the side surface 27a and the bottom surface 27b of the contact hole 27. The bottom surface 27b corresponds to the top surface 16a of the copper wiring 16, which is shown through the contact hole 27. Therefore, an area where the titanium nitride film is formed is smaller than in the case where the first conductive film 21 is formed on the top surface 18a of the second interlayer insulating film 18, where the aluminum wiring pattern 23 is formed. Hence, a stress caused by the titanium nitride film and applied to the semiconductor substrate 11 can be eased.

The warp of the semiconductor substrate 11 caused by the titanium nitride film can be reduced while the formation of the alloy having the high electrical resistivity, which is caused by the reaction between aluminum in the aluminum wiring pattern 23 and copper in the copper wiring 16, can be prevented.

According to the semiconductor device 10 of the present embodiment illustrated in FIG. 1, the first conductive film 21 covering the side surface 27a and the bottom surface 27b of the contact hole 27 is described as an example. However, the configuration of the first conductive film 21 is not limited thereto. The first conductive film 21 need not be formed on the side surface 27a of the contact hole 27 if the first conductive film 21 covers the bottom surface 27b of the contact hole 27. This configuration also provides the same effect as the semiconductor device 10 according to the present embodiment.

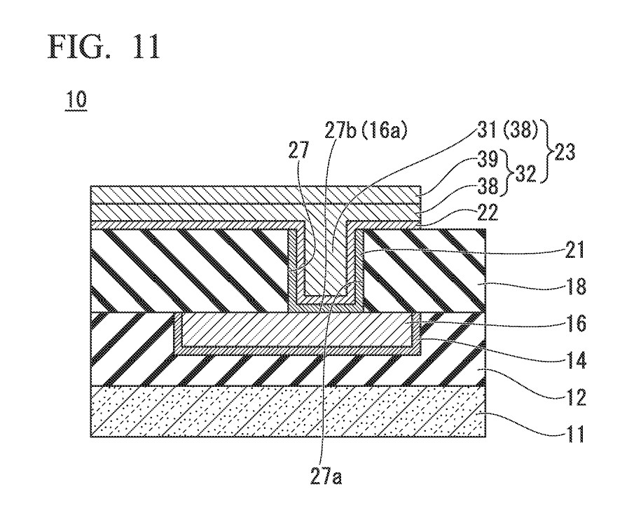

FIGS. 2 through 11 are fragmentary cross sectional elevation views illustrating the semiconductor device in a step involved in a method of forming the semiconductor device of FIG. 1 in accordance with a first preferred embodiment of the present invention. In FIGS. 2 through 11, the same reference numerals and signs are given to the same constituent elements as the semiconductor device 10 illustrated in FIG. 1. In the steps of FIGS. 10 and 11, since a first aluminum film 38 is united to a second aluminum film 39, a boundary between the first aluminum film 38 and the second aluminum film 39 does not exist. However, the boundary between the first aluminum film 38 and the second aluminum film 39 is schematically illustrated in FIGS. 10 and 11 for convenience in the explanation.

A method for forming the semiconductor device 10 according to the present embodiment will be described with reference to FIGS. 2 through 11.

As shown in FIG. 2, the first interlayer insulating film 12 having the groove 25 is formed on the semiconductor substrate 11. For example, a silicon oxide film (SiO₂ film) which will be processed into the first interlayer insulating film 12 is deposited on a silicon substrate which is the semiconductor substrate 11 by CVD (Chemical Vapor Deposition). Then, the groove 25 is formed on the silicon oxide film (SiO₂ film) by photolithography processes and dry-etching processes. In this manner, the first interlayer insulating film 12 having the groove 25 is formed.

The barrier film for the copper wiring 14 is deposited to cover the side surface 25a and the bottom surface 25b of the groove 25 and the top surface 12a of the first interlayer insulating film 12. After this, a copper film 35 which is a base material of the copper wiring 16 is deposited on the bather film for the copper wiring 14. The copper film 35 fills the groove 25. The bather film for the copper wiring 14 may be formed by sequentially depositing a tantalum nitride film (TaN film) and a tantalum film (Ta film), for example.

Unnecessary portions of the barrier film for the copper wiring 14 and the copper film 35 which are above the top surface 12a of the first interlayer insulating film 12 are removed by CMP (Chemical Mechanical Polishing). Thereby, the barrier film for the copper wiring 14 and the copper film 35 remains in the groove 25.

By doing this, the copper wiring 16 and the bather film for the copper wiring 14 are formed in the groove 25. The top surface 16a of the copper wiring 16 is substantially flush with the top surface 12a of the first interlayer insulating film 12. In other words, the barrier film for the copper wiring 14 and the copper wiring 16 are formed in the groove 25 by Damascene processes.

The second interlayer insulating film 18 having the contact hole 27 is formed on the top surface 12a of the first interlayer insulating film 12 and on the top surface 16a of the copper wiring 16. A portion of the top surface 16a of the copper wiring 16 is shown through the contact hole 27.

For example, a silicon oxide film (SiO₂ film) which is processed into the second interlayer insulating film 18 is deposited by CVD. Then, the contact hole 27 is formed in the silicon oxide film (SiO₂ film) by photolithography processes and dry-etching processes. Thereby, the second interlayer insulating film 18 having the contact hole 27 is formed. The contact hole 27 is defined by inner surfaces corresponding to the side surface 27a and the bottom surface 27b. The bottom surface 27b is configured by the portion of the top surface 16a of the copper wiring 16.

Before (just before) forming the first conductive film 21, the semiconductor substrate 11 is heated at, for example, about 300° C. in a hydrogen atmosphere to reduce and remove a natural oxide film (not shown) formed on the top surface 16a of the copper wiring 16, which is exposed through the contact hole 27.

By doing this, the rise of resistance between the first conductive film 21 and the copper wiring 16 caused by the existence of the natural oxide film can be prevented.

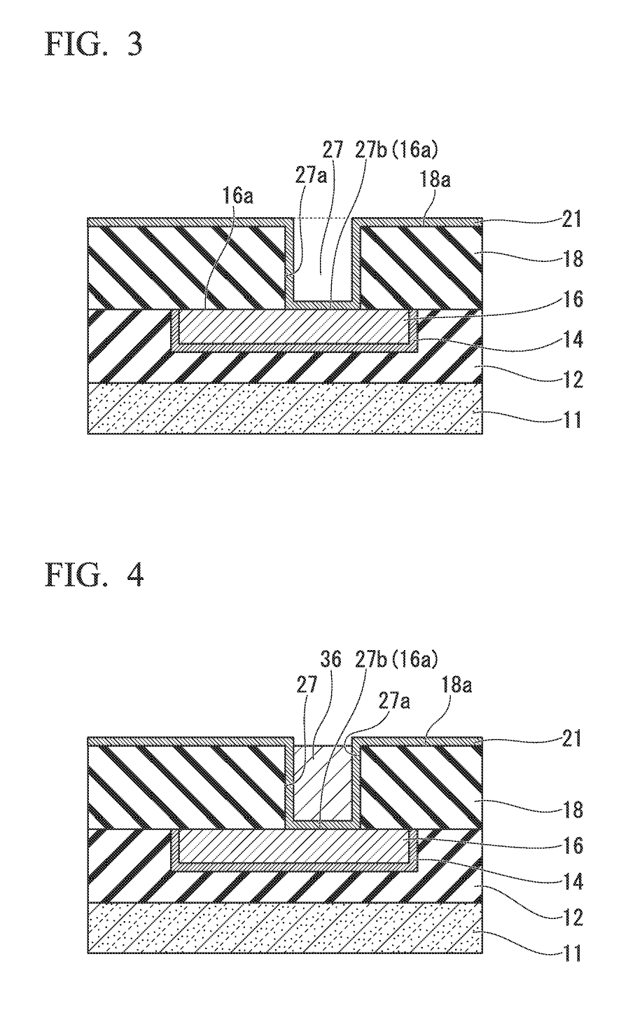

As shown in FIG. 3, the first conductive film 21 including a titanium nitride film is formed by sputtering to cover the side surface 27a and the bottom surface 27b of the contact hole 27 and the top surface 18a of the second interlayer insulating film 18. For example, a single layer of a titanium nitride film with a thickness of, for example, 30 nm is deposited by sputtering as the first conductive film 21.

As the first conductive film 21, a single layer of the titanium nitride film or a lamination of the titanium nitride film and other metal film (for example, a titanium film (Ti film), a tantalum film (Ta film), a tungsten film (W film), or a film of nitride of titanium, tantalum, or tungsten) may be used.

As shown in FIG. 4, a photoresist film 36 filling the contact hole 27 in which the first conductive film 21 is formed is formed.

For example, the photo resist film 36 is applied to fill the contact hole 27 in which the first conductive film 21 is formed. Then, the photoresist film 36 is entirely exposed and developed. Thereby, the photoresist film 36 remains only in the contact hole 27.

After these processes, the first conductive film 21 formed on the top surface 18a of the second interlayer insulating film 18 is not covered by the photoresist film 36.

Instead of the entire exposure, a reticle including a mask covering a formation region of the contact hole 27 is prepared, and the photoresist film 36 may be exposed through the reticle. Then, the photoresist film 36 is developed. After these processes, the photoresist film 36 remains only in the contact hole 27.

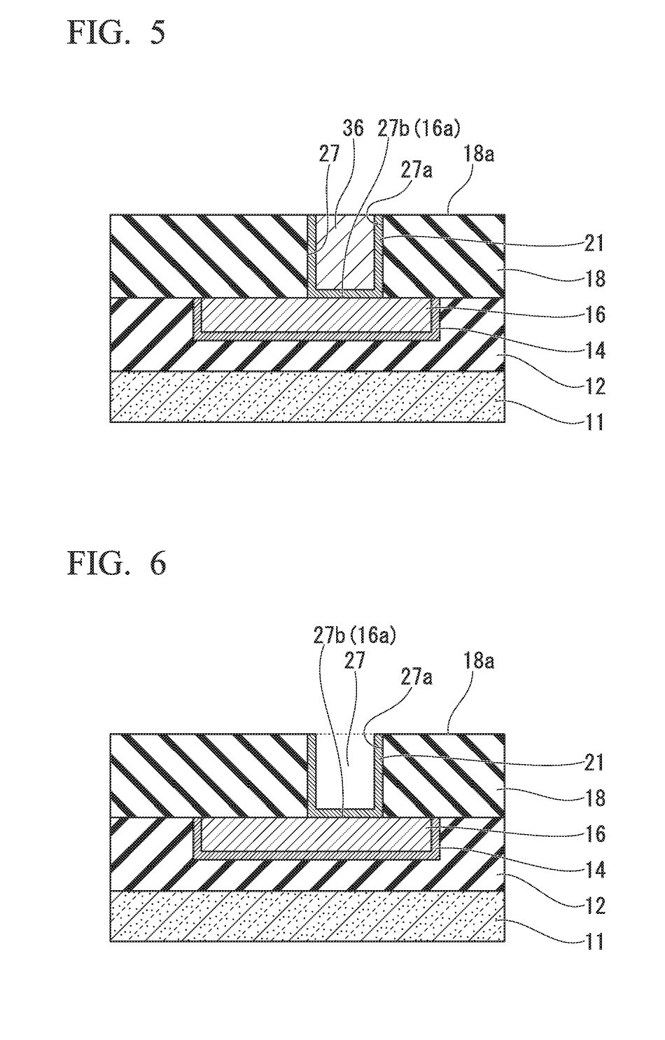

As shown in FIG. 5, an unnecessary portion of the first conductive film 21 formed on the top surface 18a of the second interlayer insulating film 18 is selectively removed by dry-etching process (etching-back process) using the photoresist film 36 as a mask.

By doing this, the first conductive film 21 illustrated in FIG. 1 is formed in the contact hole 27. The first conductive film 21 covers the side surface 27a and the bottom surface 27b of the contact hole 27. The dry-etching process described above is performed in a condition where the first conductive film 21, which is the titanium nitride film in the present embodiment, can be selectively etched.

In this manner, when the first aluminum film 38 illustrated in FIG. 8 which is the base material of the aluminum wiring pattern 23 is annealed, the first conductive film 21 which is the barrier film including titanium nitride film prevents the formation of the alloy having the high electrical resistivity, which is caused by reacting copper in the copper wiring 16 and aluminum in the first aluminum film 38. The first conductive film 21 is formed on only the side surface 27a and the bottom surface 27b of the contact hole 27. The bottom surface 27b corresponds to the top surface 16a of the copper wiring 16, which is shown through the contact hole 27. Therefore, an area where the titanium nitride film is formed is smaller than in the case where the first conductive film 21 is formed on the top surface 18a of the second interlayer insulating film 18, where the aluminum wiring pattern 23 is formed. Hence, a stress caused by the titanium nitride film and applied to the semiconductor substrate 11 can be eased.

The warp of the semiconductor substrate 11 caused by the titanium nitride film can be reduced while the formation of the alloy having the high electrical resistivity, which is caused by the reaction between aluminum in the first aluminum film 38 (aluminum wiring pattern 23) and copper in the copper wiring 16, can be prevented.

As shown in FIG. 6, the photoresist film 36 remaining in the contact hole 27 as shown in FIG. 5 is removed. For example, the photoresist film 36 is removed by wet-etching process or ashing process.

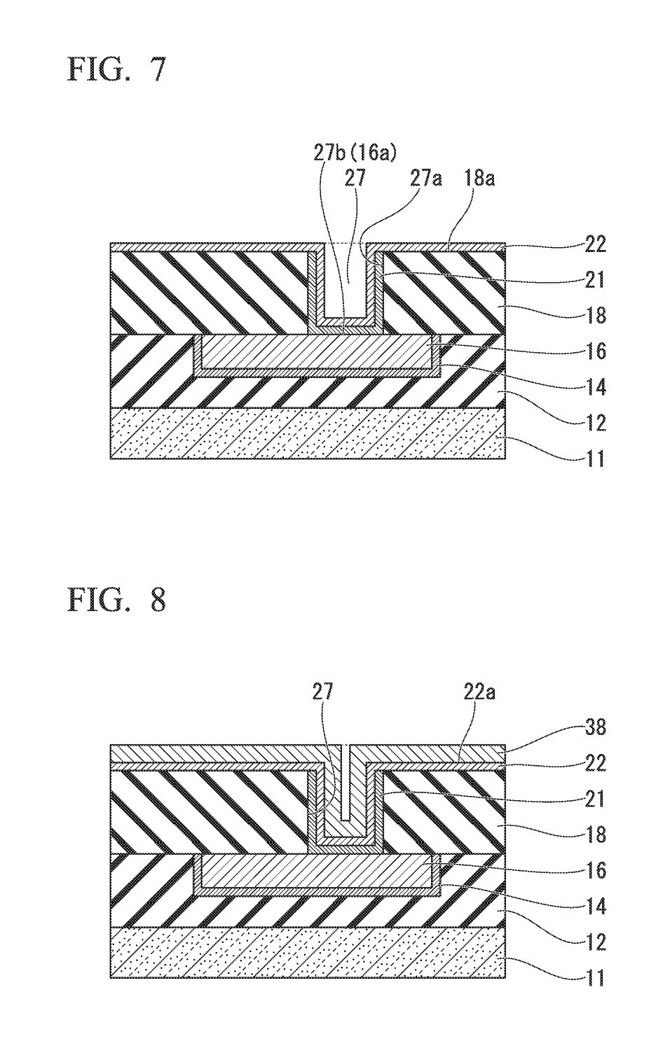

As shown in FIG. 7, the second conductive film 22 is formed to cover the side surface 27a and the bottom surface 27b of the contact hole 27 and the top surface 18a of the second interlayer insulating film 18. The thickness of the second conductive film 22 is adjusted so as not to fill the contact hole 27. The second conductive film 22 does not include the titanium nitride film.

For example, a single layer of a titanium film with a thickness of, for example, 20 nm is deposited by sputtering as the second conductive film 22. At this stage, the second conductive film 22 is not patterned.

By forming the titanium film as the second conductive film 22 on which the first aluminum film 38 will be formed, the first aluminum film 38 can be easily liquidized (reflow) in the annealing process illustrated in FIG. 9 described later. Thereby, the first aluminum film 38 steadily fills the contact hole 27.

The first conductive film 21 which is the barrier layer including titanium nitride film does not facilitate the fluidization (reflow) of the aluminum film. Therefore, it is necessary to form the second conductive film 22 in a region where the first aluminum film 38 is formed.

The second conductive film 22 is not limited to the single layer of the titanium film but may be a film which does not including the titanium nitride film having high compressive stress. For example, a lamination of metal films which are not the titanium nitride film may be used as the second conductive film 22.

Considering the annealing process illustrated in FIG. 9, in the case where the second conductive film 22 is the lamination, the titanium film is preferable as the top film of the lamination film since the titanium film facilitates a fluidization (reflowing) of the first aluminum film 38.

As shown in FIG. 8, the first aluminum film 38 is deposited on a surface 22a of the second conductive film 22 by sputtering. The first aluminum film 38 is formed to have a thickness such that the contact hole 27 in which the second conductive film 22 is formed is buried with the first aluminum film 38.

As shown in FIG. 8, the contact hole need not be fully filled with the first aluminum film 38. The first aluminum film 38 is a film which will be part of the contact plug 31 and the wiring 32. A material of the first aluminum film 38 may be, but is not limited to, an alloy including aluminum, for example, Al-Si-Cu alloy.

As shown in FIG. 9, the contact hole 27 in which the first and second conductive films 21 and 22 are formed is filled with the first aluminum film 38 by annealing the semiconductor substrate 11 and fluidizing (reflowing) the first aluminum film 38. For example, the semiconductor substrate 11 illustrated in FIG. 8 is annealed at high temperature (400° C. to 500° C.) in argon atmosphere. Thereby, the contact hole 27 in which the first and second conductive films 21 and 22 are formed is filled with the first aluminum film 38.

The contact plug 31 made of the first aluminum film 38 is formed in the contact hole 27.

As shown in FIG. 9, the first aluminum film 38 which is formed on the top surface 18a of the second interlayer insulating film 18 is too thin to form the wiring 32 illustrated in FIG. 1. Therefore, the second aluminum film 39 needs to be deposited in the later step illustrated in FIG. 10.

The reason for not forming the first aluminum film 38 at high temperature (400° C. to 500° C.) by sputtering is as follows. Since aluminum easily aggregates, sputtered and deposited aluminum instantly aggregates on the surface of the aluminum film if the semiconductor substrate 11 is kept at high temperature (400° C. to 500° C.). Therefore, the contact hole 27 cannot be filled (buried) with the first aluminum film 38. As shown in FIG. 10, the second aluminum film 39 is deposited on the first aluminum film 38 by sputtering. At this process, the second aluminum film 39 is deposited to have a thickness such that the sum of the thicknesses of the first and second aluminum films 38 and 39 formed on the top surface 18a of the second interlayer insulating film 18 is approximately equal to the thickness of the wiring 32 illustrated in FIG. 1.

As shown in FIG. 11, the wiring 32 which is united to the contact plug 31 is formed by patterning the first and second aluminum films 38 and 39 illustrated in FIG. 10.

For example, a photoresist film (not shown) covering only a formation region of the wiring 32 within a top surface 39a of the second aluminum film 39 illustrated in FIG. 10 is formed. Then, the first and second aluminum films 38 and 39 are anisotropically etched (dry-etched) using the photoresist film as a mask, thereby forming the wiring 32. Thereby, the aluminum wiring pattern 23 including the contact plug 31 and the wiring 32 is formed and the semiconductor device 10 of the present embodiment is formed.

According to the method for forming the semiconductor device of the present embodiment, when the first aluminum film 38 which is the base material of the aluminum wiring pattern 23 is annealed, the first conductive film 21 which is the barrier film including titanium nitride film prevents the formation of the alloy having the high electrical resistivity, which is caused by reacting copper in the copper wiring 16 and aluminum in the aluminum wiring pattern 23. The first conductive film 21 is formed on only the side surface 27a and the bottom surface 27b of the contact hole 27. The bottom surface 27b corresponds to the top surface 16a of the copper wiring 16, which is shown through the contact hole 27. Therefore, an area where the titanium nitride film is formed is smaller than in the case where the first conductive film 21 is formed on the top surface 18a of the second interlayer insulating film 18, where the aluminum wiring pattern 23 is formed. Hence, a stress caused by the titanium nitride film and applied to the semiconductor substrate 11 can be eased.

The warp of the semiconductor substrate 11 caused by the titanium nitride film can be reduced while the formation of the alloy having the high electrical resistivity, which is caused by the reaction between aluminum in the first aluminum film 38 (the aluminum wiring pattern 23) and copper in the copper wiring 16, can be prevented.

As used herein, the following directional terms “forward, rearward, above, downward, vertical, horizontal, below, and transverse” as well as any other similar directional terms refer to those directions of an apparatus equipped with the present invention. Accordingly, these terms, as utilized to describe the present invention should be interpreted relative to an apparatus equipped with the present invention.

The term “configured” is used to describe a component, section or part of a device which includes hardware and/or software that is constructed and/or programmed to carry out the desired function.

Furthermore, the particular features, structures, or characteristics may be combined in any suitable manner in one or more embodiments.

The terms of degree such as “substantially,” “about,” and “approximately” as used herein mean a reasonable amount of deviation of the modified term such that the end result is not significantly changed. For example, these terms can be construed as including a deviation of at least ±5 percents of the modified term if this deviation would not negate the meaning of the word it modifies.

It is apparent that the present invention is not limited to the above embodiments, but may be modified and changed without departing from the scope and spirit of the invention.

What is claimed is:

1. A device comprising:
a first conductive film including copper;
a first insulating film over the first conductive film, the first insulating film having a first contact hole, the contact hole reaching a first surface of the first conductive film;
a second conductive film including aluminum, the second conductive film being in the contact hole;
a third conductive film including titanium nitride, the third conductive film being in the first contact hole, the third conductive film covering a part of the first surface of the first conductive film; and
a fourth conductive film free of titanium nitride being disposed between the second and third conductive films.

2. The device according to claim 1, wherein the third conductive film is in contact with the part of the first surface of the first conductive film.

3. The device according to claim 1, wherein the fourth conductive film is disposed between the first insulating film and the second conductive film outside the first contact hole.

4. The device according to claim 1, wherein the fourth conductive film is a titanium film.

5. The device according to claim 1, wherein the fourth conductive film is a metal film free of titanium nitride.

6. The device according to claim 1, wherein the fourth conductive film further covers a side surface of the first contact hole.

7. The device according to claim 1, wherein the second conductive film includes an alloy containing aluminum.

8. The device according to claim 1, wherein the fourth conductive film is in contact with the second conductive film.

9. The device according to claim 1, wherein the second conductive film comprises a contact plug in the first contact hole and an interconnect extending over the first insulating film, and
wherein the third and fourth films are between the contact plug and the first conductive film.

10. The device according to claim 1, further comprising:
a second insulating film having a groove in which the first conductive film is disposed, the second insulating film extending under the first insulating film.

11. A device comprising:
a first conductive film including copper;
a second conductive film including a titanium nitride containing layer and a titanium nitride free layer, the titanium nitride containing layer being in contact with the first conductive film; and
a third conductive film including aluminum, the third conductive film being in contact with the titanium nitride free layer.

12. The device according to claim 11, further comprising:
a first interlayer insulating film between the first conductive film and the third conductive film, the first interlayer insulating film having a contact hole reaching the first conductive film, and the titanium nitride containing layer being in the first contact hole.

13. The device according to claim 12, wherein the titanium nitride containing layer covers a side surface of the contact hole.

14. The device according to claim 11, wherein the titanium nitride free layer is made of titanium.

15. The device according to claim 12, wherein the third conductive film comprises a contact plug in the first contact hole and an interconnect extending over the first insulating film, the second conductive film is disposed between the contact plug and the first conductive film.

16. A semiconductor device comprising:
a semiconductor substrate;
a first interlayer insulating film over the semiconductor substrate, the first interlayer insulating film having a groove;
a first conductive film including copper, the first conductive film being in the groove;
a second interlayer insulating film over the first conductive film, the second interlayer insulating film having a contact hole reaching the first conductive film;
a contact plug in the contact hole, the contact plug being in contact with the first conductive film, the contact plug comprising second, third, and fourth conductive films, the second conductive film being in contact with the first conductive film, the second conductive film including titanium nitride, the third conductive film being free of titanium nitride, the third conductive film being positioned between the second conductive film and the fourth conductive film and between the fourth conductive film and the second interlayer insulating film, and the fourth conductive film including aluminum; and
an interconnect extending over the contact plug and the second interlayer insulating film, the interconnect being coupled to the first conductive film through the contact plug.

17. The semiconductor device according to claim 16, wherein the interconnect comprises the third and fourth conductive films, and
wherein the third conductive film is in contact with a surface of the second interlayer insulating film.

18. The semiconductor device according to claim 16, wherein the second conductive film covers a side surface of the contact hole.

19. The semiconductor device according to claim 16, wherein the third conductive film is made of titanium.

20. The semiconductor device according to claim 16, wherein the second conductive film is in contact with the third conductive film, and
wherein the third conductive film is in contact with the fourth conductive film.
